(19) United States
(12) Patent Application Publication
(10) Pub. No.: US 2026/0190684 A1
(43) Pub. Date: Jul. 2, 2026

(54) DISPLAY PANEL AND PREPARATION METHOD THEREOF, AND DISPLAY APPARATUS

(71) Applicant: Everdisplay Optronics (Shanghai) Co., Ltd., Shanghai (CN)

(72) Inventors: Yeping SHEN, Shanghai (CN); Xianye WANG, Shanghai (CN); Ssuchun PENG, Shanghai (CN); Xiquan LI, Shanghai (CN)

(73) Assignee: Everdisplay Optronics (Shanghai) Co., Ltd., Shanghai (CN)

(21) Appl. No.: 18/845,445

(22) PCT Filed: Apr. 18, 2023
(86) PCT No.: PCT/CN2023/088876

§ 371 Date: Sep. 10, 2024

(30) Foreign Application Priority Data
Mar. 20, 2023 (CN) 202310274422.7

(51) Int. Cl. H10K 59/131; H10K 59/12; H10K 59/80

(52) U.S. Cl. CPC H10K 59/131; H10K 59/1201; H10K 59/873

(57) ABSTRACT

A display panel and a preparation method thereof, and a display apparatus, where the display panel includes at least one opening area for setting a camera module, and the method includes the following steps: providing an array substrate; preparing a data line layer on a side of the array substrate; preparing a passivation layer on a side of the data line layer away from the array substrate; etching the passivation layer and the data line layer to form at least one channel that sequentially penetrates the passivation layer and the data line layer and surrounds the opening area; and laterally etching the data line layer within the channel, so that at least one undercut structure is formed on a sidewall of the data line layer.

### TECHNICAL FIELD

The present disclosure relates to the field of display technology, and particularly, to a display panel and a preparation method thereof, and a display apparatus.

### BACKGROUND

With the development of display technology, more and more display panels and display apparatuses are applied in people's daily life and work. In order to improve the user experience, sensor modules, such as cameras, infrared sensors, etc., are usually integrated into existing display panel structures.

At present, in order to increase the screen-to-body ration, it is usually necessary to open a blind hole on the display screen, that is, to form a punch hole screen. The above-mentioned punch hole screen includes a display area and a non-display area. The display area is used to realize the display function, and the non-display area (mainly refers to the area where a blind hole is opened) is used to arrange components such as a camera. For the punch hole screen, a Slit area is usually provided at the edge of the area where the blind hole is opened to isolate the cathode, so as to prevent the luminescent material in the display area from being affected by the cathode invaded by water and oxygen within the Slit area.

The film layer structure within the Slit area generally includes a pixel array substrate and a data line layer. The data line layer needs to be etched laterally to form an undercut structure to isolate the cathode, so as to achieve the effect of laterally blocking water and oxygen. The data line layer includes an interconnecting metal, an upper barrier layer metal above the interconnecting metal, and a lower barrier layer metal below the interconnecting metal. After the interconnecting metal of the data line layer is etched laterally to form an inwardly shrinking structure, the upper barrier layer metal may bend downward. And if the degree of downward bending is large, it will directly lead to a reduction in the inwardly shrinking depth of the undercut structure, which may result in the function of isolating cathode of the encapsulation structure being ineffective, and further lead to the failure of the function of blocking water and oxygen of the undercut structure, thereby affecting product reliability.

It should be noted that the information disclosed in the above background section is only used for enhancing the understanding of the background of the present disclosure, and therefore may include information that does not constitute prior art known to those of ordinary skill in the art.

### SUMMARY

In view of this, the present disclosure provides a display panel and a preparation method thereof, and a display apparatus, which are favorable to ensuring the reliability of the function of isolating cathode of the undercut structure in the opening area of the display screen, that is, favorable to ensuring the reliability of the function of blocking water and oxygen of the undercut structure.

According to one aspect of the present disclosure, a method for preparing a display panel is provided, where the display panel includes at least one opening area for setting a camera module, and the method includes the following steps:
S110, providing an array substrate;
S120, preparing a data line layer on a side of the array substrate;
S130, preparing a passivation layer on a side of the data line layer away from the array substrate;
S140, etching the passivation layer and the data line layer to form at least one channel that sequentially penetrates the passivation layer and the data line layer and surrounds the opening area; and
S150, laterally etching the data line layer within the channel, so that at least one undercut structure is formed on a sidewall of the data line layer.

Optionally, the step S140 includes:
in the channel formed by etching, a sidewall of the passivation layer and the sidewall of the data line layer being located on a same plane.

Optionally, the data line layer includes an interconnecting metal, an upper barrier layer metal located on a side of the interconnecting metal away from the array substrate, and a lower barrier layer metal located on a side of the interconnecting metal close to the array substrate; and the step S140 includes:
the sidewall of the passivation layer, a sidewall of the upper barrier layer metal, a sidewall of the interconnecting metal, and a sidewall of the lower barrier layer metal being located on the same plane after the etching is completed.

Optionally, the step S150 includes:
laterally etching only the interconnecting metal, so that both the upper barrier layer metal and the lower barrier layer metal are at least partially exposed from the interconnecting metal.

Optionally, the step S140 includes:
etching a stacked structure formed by the passivation layer and the data line layer from top to bottom.

Optionally, in the step S150, a spacing between two adjacent interconnecting metals is greater than a spacing between two adjacent passivation layers after the lateral etching is completed.

Optionally, the method further includes the following step:
preparing an encapsulation layer on a side of the passivation layer away from the data line layer, where the encapsulation layer covers the channel, the passivation layer, and the undercut structure.

According to another aspect of the present disclosure, a display panel prepared by any of the above preparation methods is provided, and the display panel includes:
an array substrate;
a data line layer, arranged on a side of the array substrate; where a sidewall of the data line layer is laterally etched to form at least one undercut structure; and
a passivation layer, arranged on a side of the data line layer away from the array substrate and covering the data line layer.

Optionally, the data line layer includes an interconnecting metal, an upper barrier layer metal located on a side of the interconnecting metal away from the array substrate, and a lower barrier layer metal located on a side of the interconnecting metal close to the array substrate; and both the upper barrier layer metal and the lower barrier layer metal are at least partially exposed from the interconnecting metal.

Optionally, the passivation layer covers the upper barrier layer metal.

According to another aspect of the present disclosure, a display apparatus is provided, and the display apparatus includes the above display panel.

The beneficial effects of the present disclosure compared to the related art are as follows.

The display panel and the preparation method thereof, and the display apparatus provided by the present disclosure reduce the degree of downward bending of the upper barrier layer metal in the data line layer by laying the passivation layer on top of the data line layer and utilizing the surface tension of the passivation layer disposed on top of the data line layer, so as to avoid the problem that the inwardly shrinking depth of the undercut structure in the data line layer becomes smaller caused by a large degree of downward bending, which further leads to a failure of the function of blocking water and oxygen of the undercut structure, and are favorable to ensuring the reliability of the function of isolating cathode of the undercut structure in the opening area of the hole-digging display, that is, favorable to ensuring the reliability of the function of blocking water and oxygen of the undercut structure, thereby favorable to enhancing the reliability of the display product.

On the other hand, in combination with the following improvement with respect to the aspect of the preparation process: instead of etching the data line layer first and then preparing the passivation layer, the data line layer and the passivation layer are etched and completed together after the passivation layer is prepared, a problem that the etching cannot be performed due to the passivation layer covering the sidewall of the data line layer is avoided.

### BRIEF DESCRIPTION OF THE DRAWINGS

The accompanying drawings herein, which are incorporated in and constitute a part of this specification, illustrate embodiments consistent with the present disclosure and are used in conjunction with the specification to explain the principles of the present disclosure. Obviously, the drawings in the following description are only some embodiments of the present disclosure. For those of ordinary skill in the art, other drawings may also be obtained from these drawings without paying creative effort.

FIG. 1 is a structural top view of a display panel disclosed by an embodiment of the present disclosure;

FIG. 2 is a partially enlarged schematic diagram of an edge area of an opening of the display panel in FIG. 1;

FIG. 3 is a cross-sectional view along the A-A direction of the edge area of the opening in FIG. 2;

FIG. 4 is a schematic diagram of the panel structure formed in a case that the data line layer is directly etched to form a channel, and a passivation layer is then laid on top in the preparation process of the display panel;

FIG. 5 is a schematic flowchart of a preparation method for a display panel disclosed in an embodiment of the present disclosure;

FIG. 6 is a schematic diagram of the panel structure after the process at step S120 of the preparation method disclosed in FIG. 5 is completed;

FIG. 7 is a schematic diagram of the panel structure after the process at step S130 of the preparation method disclosed in FIG. 5 is completed; and

FIG. 8 is a schematic diagram of the panel structure after the process at step S140 of the preparation method disclosed in FIG. 5 is completed.

### REFERENCE SIGNS

11, Opening area; 12, Edge area of the opening; 13, Display area; 14, First annular pattern; 15, Second annular pattern; 16, Array substrate; 17, Data line layer; 18, Passivation layer; 19, Channel; 20, Undercut structure; 21, Interconnecting metal; 22, Upper barrier layer metal; 23, Lower barrier layer metal

### DETAILED DESCRIPTION

Exemplary implementation manners will now be described more comprehensively with reference to the accompanying drawings. However, the exemplary implementation manners may be implemented in various forms and should not be construed as being limited to the implementation manners set forth herein. Rather, these implementation manners are provided so that the present disclosure will be thorough and complete, and the concept of the exemplary implementation manners may be comprehensively conveyed to those skilled in the art. The described features, structures, or characteristics may be combined in any suitable manner in one or more implementation manners. In the following description, numerous specific details are provided in order to provide a thorough understanding of the implementation manners of the present disclosure. However, one skilled in the art will appreciate that the technical solutions of the present disclosure may be practiced without one or more of the specific details, or that other methods, materials, apparatuses, etc. may be employed. In other instances, well-known technical solutions are not shown or described in detail to avoid obscuring aspects of the present disclosure. The same reference numerals in the drawings denote the same or similar structures, and thus their detail descriptions will be omitted.

The terms “a”, “an”, “the”, “said” and “at least one” are used to indicate the existence of one or more elements/components/etc.; and the terms “comprising”, “having” and “providing” are used in an open-ended inclusion and refer to the existence of additional elements/components/etc., in addition to the listed elements/components/etc.

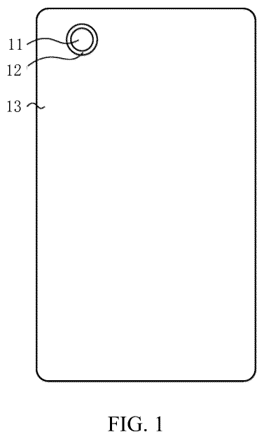

As shown in FIG. 1, an embodiment of the present disclosure discloses a display panel. The above display panel includes an opening area 11, an edge area of the opening 12 surrounding the opening area 11, and a display area 13 surrounding the edge area of the opening 12. Therefore, the display panel in the embodiment of the present disclosure is a punch hole screen. The structure of the display panel and the preparation method provided by the present disclosure are mainly applied to the edge area of the opening 12.

The opening area 11 is used for installing a sensor module such as a camera module. There may be one or more opening areas 11, that is, the present disclosure does not limit the number of the opening areas 11. The devices provided in the camera module include but are not limited to at least one of a distance sensor, a light sensor, a camera or an infrared sensor. The opening area 11 shown in the drawings of the present disclosure is circular, but the present disclosure is not limited thereto, and in other embodiments, it may also be quadrilateral or other shapes.

The edge area 12 of the opening is the Slit area, and in this area, the data line layer of the panel structure is etched to form an undercutting structure (i.e., undercut structure), where the undercut structure can isolate the cathode, so as to prevent the luminescent material in the display area from being affected by the cathode invaded by water and oxygen within the Slit area, thereby achieving the purpose of laterally blocking water and oxygen after cutting.

The display area 13 is used to realize a display function of the display panel, and light emitting units are arranged in this area. Exemplarily, the light emitting unit may be an organic light emitting unit, a liquid crystal display light emitting unit, a Mini-LED, a Micro-LED or other types of light emitting units known to those skilled in the art, which are not limited in the embodiments of the present disclosure.

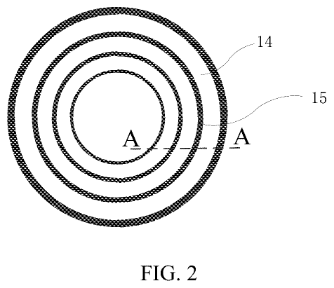

Referring to FIG. 2, the edge area of the opening of the display panel disclosed in this embodiment consist of first annular patterns 14 filled with blank areas and second annular patterns 15 filled with shaded areas. The numbers of the first annular patterns 14 and the second annular patterns 15 shown in FIG. 2 are only for illustration, and the present disclosure does not limit the numbers thereof.

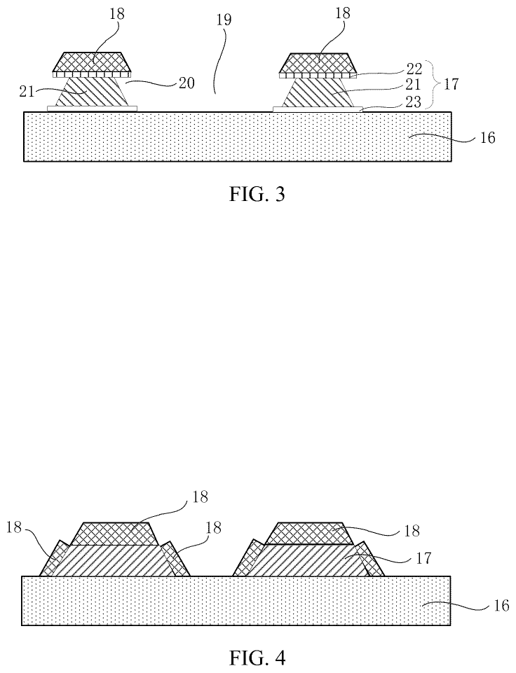

FIG. 3 is a partial cross-sectional view along the A-A direction of the edge area of the opening in FIG. 2. Referring to FIG. 3, the display panel in this area includes, in an order from bottom to top, an array substrate 16, a data line layer (DL) 17 and a passivation layer (BP) 18. The array substrate 16 may include a substrate and an underlying structure. The data line layer 17 is arranged on a side of the above array substrate 16. The sidewall of the data line layer 17 is laterally etched to form at least one undercut structure 20. The undercut structure 20 is formed by etching the sidewall on each side of the data line layer 17 as illustrated in FIG. 3. The passivation layer 18 is arranged on the side of the data line layer 17 away from the array substrate 16, and the passivation layer 18 is able to completely cover the above data line layer 17.

The data line layer 17 in this embodiment includes an interconnecting metal 21, an upper barrier layer metal 22 located on a side of the interconnecting metal 21 away from the array substrate 16, and a lower barrier layer metal 23 located on a side of the interconnecting metal 21 close to the array substrate 16. Both the upper barrier layer metal 22 and the lower barrier layer metal 23 are at least partially exposed from the interconnecting metal 21. Exemplarily, the upper barrier layer metal 22 and the lower barrier layer metal 23 may, for example, be made of titanium, which is not limited in the present disclosure.

Continuing to refer to FIG. 3, a portion of each of the two sides of the upper barrier layer metal 22 is exposed from the interconnecting metal 21, and a portion of each of the two sides of the lower barrier layer metal 23 is exposed from the interconnection metal 21. Further, in this embodiment, only the interconnecting metal 21 in the data line layer 17 is etched laterally from its two sidewalls, and the upper barrier layer metal 22 and the lower barrier layer metal 23 are not etched, so that the corresponding undercut structure 20 is formed. Since in the edge area of the opening of the display panel, the cathode is generally arranged between an encapsulation layer and the data line layer 17, the undercutting structure 20 may cut off the cathode in the area in which the structure is located, so that the continuous cathode is changed to a discontinuous cathode, thereby preventing the luminescent material, such as OLED material, in the display area from being affected by the cathode invaded by water and oxygen within the Slit area. That is, by disconnecting the cathode in the area of the undercut structure 20, the luminescent material in the display area will not be connected to the cathode intruded by water and oxygen.

Through the above structure, the passivation layer 18 in this embodiment is able to completely cover the upper barrier layer metal 22, so that the surface tension of the passivation layer 18 can be utilized to reduce the degree of downward bending of the upper barrier metal layer 22 in the data line layer 17, so as to avoid the problem that the inwardly shrinking depth of the undercut structure 20 in the data line layer 17 becomes small caused by a large degree of downward bending, which does not meet the depth requirement of the encapsulation and leads to a failure of the function of blocking water and oxygen of the undercut structure 20. The above structure are favorable to ensuring the reliability of the function of isolating the cathode of the undercut structure 20 in the opening area of the hole-digging display, that is, favorable to ensuring the reliability of the function of blocking water and oxygen of the undercut structure 20, thereby favorable to enhancing the reliability of the display product.

In some optional embodiments, in the data line layer 17, both the extension length of the upper barrier layer metal 22 along the radial direction of the opening area and the extension length of the lower barrier layer metal 23 along the radial direction of the opening area are greater than the extension length of the interconnecting metal 21 along the radial direction of the opening area. Before the undercut structure 20 is formed, a spacing between two adjacent data line layers 17 is smaller than a spacing between two adjacent passivation layers 18. After the undercut structure 20 is formed, a spacing between the interconnecting metals 21 in two adjacent data line layers 17 is greater than a spacing between two adjacent passivation layers 18.

Referring to FIG. 3, the passivation layer 18 and the data line layer 17 are stacked to form a stacked structure, and a channel 19 is formed between adjacent two stacked structures. The above channel 19 extends around the opening area and closes to form the above first annular pattern 14, and the above stacked structure extends around the opening area and closes to form the above second annular pattern 15.

During specific implementation, in the process of manufacturing the above display panel, if the passivation layer 18 is laid on the top of the data line layer 17 after performing preliminary etching on the data line layer 17, the material of the passivation layer 18 will remain on the sidewalls of the data line layer 17 (as shown in FIG. 4) after the passivation layer 18 is etched, which makes it impossible to further etch the sidewalls of the data line layer 17 to form the undercut structure 20. That is, the preparation process of the undercut cannot be realized.

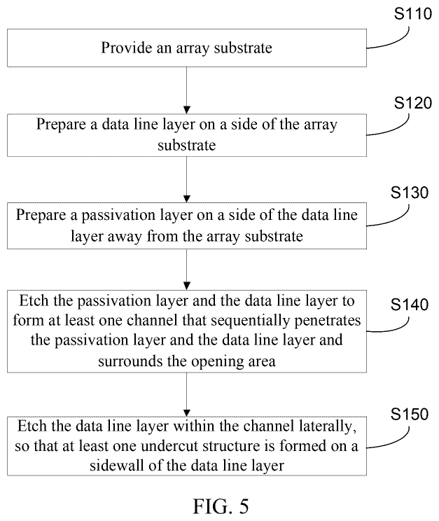

In order to solve the above problem, an embodiment of the present disclosure also discloses a preparation method for manufacturing the display panel disclosed in any one of the above embodiments. With reference to FIG. 5, the preparation method includes the following steps.

In S110, an array substrate is provided.

In S120, a data line layer is prepared on a side of the array substrate.

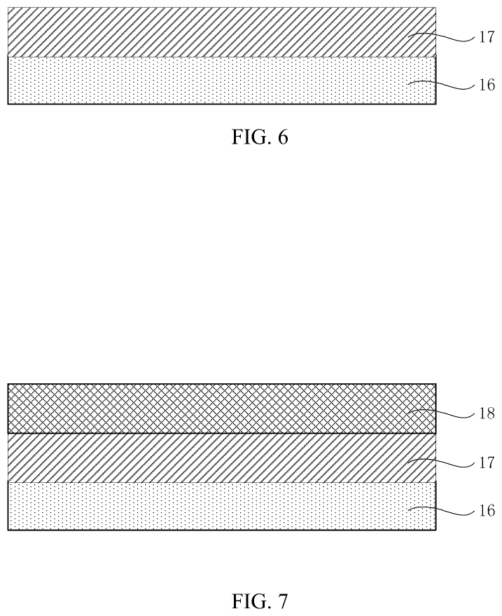

Referring to FIG. 6, in this embodiment, a data line layer 17 is prepared on the array substrate 16, and the data line layer 17 is able to completely cover the above array substrate 16.

In S130, a passivation layer is prepared on a side of the data line layer away from the array substrate.

Referring to FIG. 7, in this embodiment, a passivation layer 18 is prepared on the data line layer 17 which is not etched, and the passivation layer 18 is able to completely cover the data line layer 17 after the preparation is completed.

In S140, the passivation layer and the data line layer are etched to form at least one channel that sequentially penetrates the passivation layer and the data line layer and surrounds the opening area.

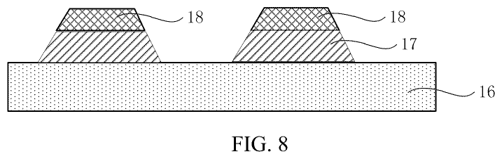

Referring to FIG. 8, in this embodiment, the stacked structure formed by the passivation layer 18 and the data line layer 17 after the preparation in the above step S130 is etched from top to bottom. That is, the passivation layer 18 and the data line layer 17 are etched together, rather than laying the passivation layer 18 after the data line layer 17 is etched. In this way, it can avoid the problem of failure of the etching or the material of the passivation layer 18 remaining on the sidewalls of the data line layer 17 in the undercut structure 20 and being unable to be removed, due to that the passivation layer 18 is coated on the sidewalls of the data line layer 17. The channel 19 formed after the preparation in this step extends around the opening area and closes to form the above first annular pattern 14.

Referring to FIG. 8, in the channel 19 formed after the preparation in step S140 is completed, the sidewall of the passivation layer 18 and the sidewall of the data line layer 17 are located on the same plane. That is, after the etching is completed, the sidewall of the above passivation layer 18, the sidewall of the above upper barrier layer metal 22, the sidewall of the interconnecting metal 21, and the sidewall of the lower barrier layer metal 23 are located on the same plane.

And in S150, the data line layer within the channel is laterally etched, so that at least one undercut structure is formed on the sidewall of the data line layer.

In this step, only the interconnecting metal 21 in the data line layer 17 is laterally etched, so that both the upper barrier layer metal 22 and the lower barrier layer metal 23 are partially exposed from the interconnecting metal 21, and the sidewalls on both sides of the interconnecting metal 21 respectively form the undercut structures 20. During specific implementation, this step may use an acidic solution as an etching solution, and use a wet etching process to etch the sidewalls of the data line layer 17 to form the undercut structures 20. The structure of the display panel after the preparation in step S150 is completed is shown in FIG. 3.

Further, in this embodiment, after the preparation in step S150 is completed, the spacing between the interconnecting metals 21 in two adjacent data line layers 17 is greater than the spacing between two adjacent passivation layers 18. Since there is tension on the surface of the passivation layer 18, it is beneficial for increasing the depth of side encapsulation of the undercut structure 20 and reducing the difficulty of the lateral etching process.

The improvements in the preparation process of the display panel disclosed in the above embodiments of the present disclosure are as follows. Instead of etching the data line layer first and then preparing the passivation layer, the data line layer and the passivation layer are etched together after the passivation layer is prepared, which can avoid the problem of failure of the etching or the material of the passivation layer remaining on the sidewalls of the data line layer in the undercut structure and being unable to be removed, due to that the passivation layer is coated on the sidewalls of the data line layer. On the other hand, the difficulty of the manufacturing process can also be reduced in this way, making it easier to manufacture the array segments and encapsulation, and at the same time improving the stability of the manufacturing process of the display panel.

In some optional embodiments, another method for preparing a display panel is disclosed. On the basis of the above embodiment corresponding to FIG. 5, the method also includes the following step:
preparing an encapsulation layer on a side of the passivation layer away from the data line layer, where the encapsulation layer covers the above channel, the above passivation layer, and the above undercut structure. That is, an encapsulation layer is prepared above the passivation layer, so as to ensure the water-oxygen barrier performance of the display panel. Exemplarily, the encapsulation layer can be realized by using, for example, a Chemical Vapor Deposition (CVD) process.

Some embodiments of the present disclosure further provide a display apparatus, which includes the above display panel. The display apparatus is a punch hole display apparatus, which reduces the ratio of the non-display area, for meeting the current market requirement for a display apparatus with a high screen-to-body ratio.

The display apparatus provided by the embodiments of the present disclosure may be any apparatus that displays contents regardless of whether they are dynamic (for example, video) or fixed (for example, still images), and regardless of whether they are texts or images. More particularly, it is contemplated that the described embodiments may be implemented in or associated with a variety of electronic apparatuses. The variety of electronic apparatuses may include, for example, but not limited to, a mobile phone, a wireless device, a personal data assistant (PDA), a handheld or portable computer, a GPS receiver/navigator, a camera, a MP4 video player, a camcorder, a game console, a watch, a clock, a calculator, a television monitor, a flat panel display, a computer monitor, an automotive display (e.g., an odometer display, etc.), a navigator, a cockpit control and/or display, a display for camera views (e.g., a display for a rear-view camera in a vehicle), an electronic photo, an electronic billboard or sign, a projector, an architectural structure, a packaging and an aesthetic structure, etc.

To sum up, the display panel and the preparation method thereof, and the display apparatus provided by the present disclosure have at least the following advantages.

The display panel and the preparation method thereof, and the display apparatus provided by the present disclosure reduce the degree of downward bending of the upper barrier layer metal in the data line layer by laying the passivation layer on top of the data line layer and utilizing the surface tension of the passivation layer disposed on top of the data line layer, so as to avoid the problem that the inwardly shrinking depth of the undercut structure in the data line layer becomes small caused by a large degree of downward bending, which leads to a failure of the function of blocking water and oxygen of the undercut structure, and are favorable to ensuring the reliability of the function of isolating cathode of the undercut structure in the opening area of the hole-digging display, that is, favorable to ensuring the reliability of the function of blocking water and oxygen of the undercut structure, thereby favorable to enhancing the reliability of the display product.

On the other hand, improvement with respect to the aspect of the preparation process is as follows: instead of etching the data line layer first and then preparing the passivation layer, the data line layer and the passivation layer are etched together after the passivation layer is prepared, so as to avoid the problem that the etching cannot be performed due to the passivation layer covering the sidewall of the data line layer.

The above content is a further detailed description of the present disclosure in conjunction with specific embodiments, and it cannot be considered that the specific implementation of the present disclosure is limited to these descriptions. For those of ordinary skill in the art, without departing from the concept of the present disclosure, some simple deductions or substitutions may be made, all of which should be regarded as falling within the scope of protection of the present disclosure.

1. A preparation method for a display panel, wherein the display panel comprises at least one opening area for setting a camera module, and the preparation method comprises following steps:
S110, providing an array substrate;
S120, preparing a data line layer on a side of the array substrate;
S130, preparing a passivation layer on a side of the data line layer away from the array substrate;
S140, etching the passivation layer and the data line layer to form at least one channel that sequentially penetrates the passivation layer and the data line layer and surrounds the opening area; and
S150, laterally etching the data line layer within the channel, so that at least one undercut structure is formed on a sidewall of the data line layer.

2. The preparation method for the display panel according to claim 1, wherein the step S140 comprises:
in the channel formed by etching, a sidewall of the passivation layer and the sidewall of the data line layer being located on a same plane.

3. The preparation method for the display panel according to claim 2, wherein the data line layer comprises an interconnecting metal, an upper barrier layer metal located on a side of the interconnecting metal away from the array substrate, and a lower barrier layer metal located on a side of the interconnecting metal close to the array substrate; and the step S140 comprises:
the sidewall of the passivation layer, a sidewall of the upper barrier layer metal, a sidewall of the interconnecting metal, and a sidewall of the lower barrier layer metal being located on the same plane after the etching is completed.

4. The preparation method for the display panel according to claim 3, wherein the step S150 comprises:
laterally etching only the interconnecting metal, so that both the upper barrier layer metal and the lower barrier layer metal are at least partially exposed from the interconnecting metal.

5. The preparation method for the display panel according to claim 3, wherein in the step S150, after the lateral etching is completed, a spacing between two adjacent interconnecting metals is greater than a spacing between two adjacent passivation layers.

6. The preparation method for the display panel according to claim 1, wherein the step S140 comprises:
etching a stacked structure formed by the passivation layer and the data line layer from top to bottom.

7. The preparation method for the display panel according to claim 1, wherein the method further comprises a following step:
preparing an encapsulation layer on a side of the passivation layer away from the data line layer, wherein the encapsulation layer covers the channel, the passivation layer, and the undercut structure.

8. A display panel, wherein the display panel is prepared by a preparation method, wherein the display panel comprises at least one opening area for setting a camera module, and the preparation method comprises following steps:
S110, providing an array substrate;
S120, preparing a data line layer on a side of the array substrate;
S130, preparing a passivation layer on a side of the data line layer away from the array substrate;
S140, etching the passivation layer and the data line layer to form at least one channel that sequentially penetrates the passivation layer and the data line layer and surrounds the opening area; and
S150, laterally etching the data line layer within the channel, so that at least one undercut structure is formed on a sidewall of the data line layer, and
the display panel comprises:
the array substrate;
the data line layer, arranged on a side of the array substrate; wherein a sidewall of the data line layer is laterally etched to form at least one undercut structure; and
the passivation layer, arranged on a side of the data line layer away from the array substrate and covering the data line layer.

9. The display panel according to claim 8, wherein the data line layer comprises an interconnecting metal, an upper barrier layer metal located on a side of the interconnecting metal away from the array substrate, and a lower barrier layer metal located on a side of the interconnecting metal close to the array substrate; and wherein both the upper barrier layer metal and the lower barrier layer metal are at least partially exposed from the interconnecting metal.

10. The display panel according to claim 9, wherein the passivation layer covers the upper barrier layer metal.

11. A display apparatus, comprising a display panel, wherein the display panel is prepared by a preparation method, wherein the display panel comprises at least one opening area for setting a camera module, and the preparation method comprises following steps:
S110, providing an array substrate;
S120, preparing a data line layer on a side of the array substrate;
S130, preparing a passivation layer on a side of the data line layer away from the array substrate;
S140, etching the passivation layer and the data line layer to form at least one channel that sequentially penetrates the passivation layer and the data line layer and surrounds the opening area; and
S150, laterally etching the data line layer within the channel, so that at least one undercut structure is formed on a sidewall of the data line layer, and
the display panel comprises:
an array substrate;
a data line layer, arranged on a side of the array substrate; wherein a sidewall of the data line layer is laterally etched to form at least one undercut structure; and
a passivation layer, arranged on a side of the data line layer away from the array substrate and covering the data line layer.

12. The display panel according to claim 8, wherein the step S140 comprises:
in the channel formed by etching, a sidewall of the passivation layer and the sidewall of the data line layer being located on a same plane.

13. The display panel according to claim 9, wherein the step S150 comprises:
laterally etching only the interconnecting metal, so that both the upper barrier layer metal and the lower barrier layer metal are at least partially exposed from the interconnecting metal.

14. The display panel according to claim 9, wherein in the step S150, after the lateral etching is completed, a spacing between two adjacent interconnecting metals is greater than a spacing between two adjacent passivation layers.

15. The display panel according to claim 8, wherein the step S140 comprises:
etching a stacked structure formed by the passivation layer and the data line layer from top to bottom.

16. The display panel according to claim 8, wherein the method further comprises a following step:
preparing an encapsulation layer on a side of the passivation layer away from the data line layer, wherein the encapsulation layer covers the channel, the passivation layer, and the undercut structure.

17. The display apparatus according to claim 11, wherein the step S140 comprises:
in the channel formed by etching, a sidewall of the passivation layer and the sidewall of the data line layer being located on a same plane.

18. The display apparatus according to claim 11, wherein the data line layer comprises an interconnecting metal, an upper barrier layer metal located on a side of the interconnecting metal away from the array substrate, and a lower barrier layer metal located on a side of the interconnecting metal close to the array substrate; and wherein both the upper barrier layer metal and the lower barrier layer metal are at least partially exposed from the interconnecting metal.

19. The display apparatus according to claim 18, wherein the step S150 comprises:
laterally etching only the interconnecting metal, so that both the upper barrier layer metal and the lower barrier layer metal are at least partially exposed from the interconnecting metal.

20. The display apparatus according to claim 18, wherein in the step S150, after the lateral etching is completed, a spacing between two adjacent interconnecting metals is greater than a spacing between two adjacent passivation layers.
